(19) United States
(12) Patent Application Publication
(10) Pub. No.: US 2010/0236597 A1
(43) Pub. Date: Sep. 23, 2010

(54) PHOTOVOLTAIC MODULE

(75) Inventors: Georg Napetschnig, Diex (AT); Rudolf Frank, Pischeldorf (AT); Ingram Eusch, Villach (AT)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Kioto Photovoltaics GmbH

(21) Appl. No.: 12/719,916

(22) Filed: Mar. 9, 2010

(30) Foreign Application Priority Data
Mar. 21, 2009 (EP) EP 09004083.3

(51) Int. Cl. H01L 31/042; H01L 31/18

(52) U.S. Cl. 136/244; 438/80; 257/E21.499

(57) ABSTRACT

The invention relates to a photovoltaic module. Such a photovoltaic module is also referred to as a “string” and consists of a plurality of plate-shaped cells, what are known as solar cells, which are arranged at a distance from each other and flush with each other.

### FIELD OF THE INVENTION

The invention relates to a photovoltaic module.

### BACKGROUND OF THE INVENTION

A photovoltaic module is also referred to as a “string” and comprises a plurality of plate-shaped cells, so called solar cells, which are arranged at a distance from and flush with each other. Each solar cell has a conductor track structure which forms a first electrode on a first main surface, and a second main surface is configured in each case as a second electrode with opposed polarity. All the cells are identically oriented with respect to their main surface, that is, there is a flush alignment of the respective cell main surfaces within the photovoltaic module comprising a plurality of cells. Adjacent cells are in each case connected electrically by means of at least one flat band (ribbon cable), with the flat band being soldered with a first section to the first electrode of one cell and with a second section to the second electrode of an adjacent cell.

Such a photovoltaic module is disclosed for example in DE 10 2006 058 892 A1. Here it is described that the solar cells with the conductor tracks arranged on their upper side and lower side are brought consecutively in a cyclical manner under a soldering stamp on a belt conveyor in order to produce the corresponding soldered connection between the flat band and the electrode.

In the proposal according to DE 10 2006 058 892 A1, it is furthermore provided for a thin protective layer to be arranged between the soldering stamps on one side and the cells to be connected on the other side. This is supposed to achieve that the heat necessary for the soldering process is only applied in a targeted manner to the points which are to be soldered. In other words: the soldering band (flat band) is only heated in the regions in which it is soldered on the respective cell. This produces irregularities in the edge region of a cell to such an extent that the soldering band (flat band) has a different geometry in the spaces between adjacent cells because it is not heat-treated in this region. These irregular points also form a mechanical weak point in the connection of adjacent cells.

Owing to the different thermal loading during the soldering process (over 200° C.), the cells, which usually have a thickness of less than 200 μm, tend to deform. Transporting the cells on the belt conveyor which is moved in a pulsed manner furthermore creates the risk of cell breakage.

### SUMMARY OF THE INVENTION

The invention is based on the object of providing a photovoltaic module of the specified type which does not have the described disadvantages. Furthermore, it should be possible to produce the photovoltaic module using a simplified method.

The basic idea of the invention consists in carrying out the soldering not in pairs and correspondingly not in a pulsed manner, but rather in producing a photovoltaic module comprising of a plurality of cells in a common working step, that is, in connecting a plurality of cells to each other with corresponding soldering bands in a single working step.

The result of this is that the flat bands for connecting adjacent cells are thermally loaded over their entire length and thus also in the regions between adjacent cells. This produces a more homogenous structure of the electrical connection of adjacent cells and an optimised flow of current.

In its most general embodiment, the invention relates to a photovoltaic module with the following features:
a plurality of plate-shaped cells which are arranged at a distance from each other and flush with each other,
each cell has a conductor track structure which forms a first electrode on a first main surface, and a second main surface is configured in each case as a second electrode with opposed polarity,
all the cells are oriented identically with respect to their main surface,
adjacent cells are electrically connected in each case by means of at least one flat band,
the flat band has a solderable coating on a base body,
the flat band is soldered with a first section to the first electrode of one cell and with a second section to the second electrode of an adjacent cell, wherein
the coating in the section between adjacent cells provides at at least two points a thickness which deviate from each other by at least 30%, relative (perpendicularly) to the base body of the flat band.

If the base body is considered in an idealised manner as a strips of sheet metal with two main surface which are parallel to each other, it follows that the solderable coating is arranged essentially on the main surfaces of the flat band, In the untreated state of the flat band, the coating has a more or less identical material thickness on both sides. The base body can for example consist predominantly of copper and have a width of 1-3 mm, in particular 1.5-2.5 mm, and a thickness of 0.1-0.3 mm, in particular 0.1-0.2 mm, whereas the Zn-based coating on both main surfaces is for example in each case 10-30 μm, in particular 10-20 μm, thick.

The photovoltaic module according to the invention differs from the prior art in that the coating in the section between adjacent cells has an alternating material thickness. The change compared to the untreated flat band results from the fact that this section of the flat band was also thermally loaded by the soldering stamp/lamp during the production process and the coating material was changed from the solid to the viscous/liquid state during the soldering process, so that it at least partially deformed in the said regions. This is caused in particular because the flat band does not run in a straight line in the transition region between adjacent cells, as on the main surfaces of the cells, but in an S-shaped manner, because it runs in a curved manner from a main surface of one cell to the opposite main surface of the adjacent cell. Despite the relatively low material thickness of the cells, the heating and gravitational influences result in the coating material “flowing” along the said curved sections and thus in the formation of different coating thicknesses at different points/sections of the flat band between adjacent cells. A distribution of the coating material without steps and without spontaneous changes in cross section is achieved in this manner.

The following exemplary embodiment illustrates the described effect schematically.

The deviations of the material thickness in the said region can be over 40%, over 60%, but also over 80%. So, for example, on the finished string, the coating at one point can have a material thickness of 8 μm and at another point can have a material thickness of 25 μm. The differences are often clearer, for example 2 μm at one point and 35 μm at another point.

The conductor track structure of a solar cell can for example have two parallel busbars which run at a distance from each other, with each busbar being soldered with a flat band. Further electrical conductor tracks are allocated to the busbar, which generally run at a distance from each other perpendicularly to the busbars.

The method for producing the described photovoltaic module comprises the following steps:
A first cell is placed on a support,
at least one flat band is placed with one section on the exposed first electrode of the first cell,
a second cell is placed on the second section of the flat band in such a manner that it lies at a distance from the first cell and the second electrode of the second cell contacts the second section of the flat band,
the above-mentioned steps are then repeated until the module comprises n cells,
the module with n cells is thermally loaded from at least one side in a subsequent method step in such a manner that a soldered connection is produced between the flat bands and corresponding electrodes of the cells,
the support with the module lying on it is then fed to further process steps.

These further process steps include finishing a plurality of photovoltaic modules to form relatively large units which can then be mounted for example on a roof in order to generate electricity.

The positioning of the cells on the support is made easier if the cells are placed in corresponding depressions in the support. The depressions ensure an exact orientation of the cells with respect to each other. The cells of a plurality of strings can also be soldered at the same time, specifically, not only within one string but also adjacent strings to each other.

The thermal loading, that is, the soldering of the cells can take place using halogen light. Temperatures between 150 and 250° C. are usually needed to be able to produce the soldered connections,

In principle it is sufficient to arrange the heat source(s) on one side of the strings, as the thermal energy is sufficient to solder on the flat bands which run on the opposite main surface too. According to one embodiment, however, a plurality of heat sources are provided which are arranged in front of the cells at a distance from both main surfaces of the cells. This makes the heat energy on both sides of the string uniform.

Further features of the invention can be found in the features of the subclaims and the other application documents.

### BRIEF DESCRIPTION OF THE DRAWINGS

The invention is explained in more detail below using an exemplary embodiment. In the figures, schematically in each case,

FIG. 1: shows a plan view of a photovoltaic module consisting of five solar cells.

FIG. 2: shows a side view of two adjacent solar cells.

In the figures, the same or functionally identical components are shown with the same reference numerals.

### DETAILED DESCRIPTION OF THE INVENTION

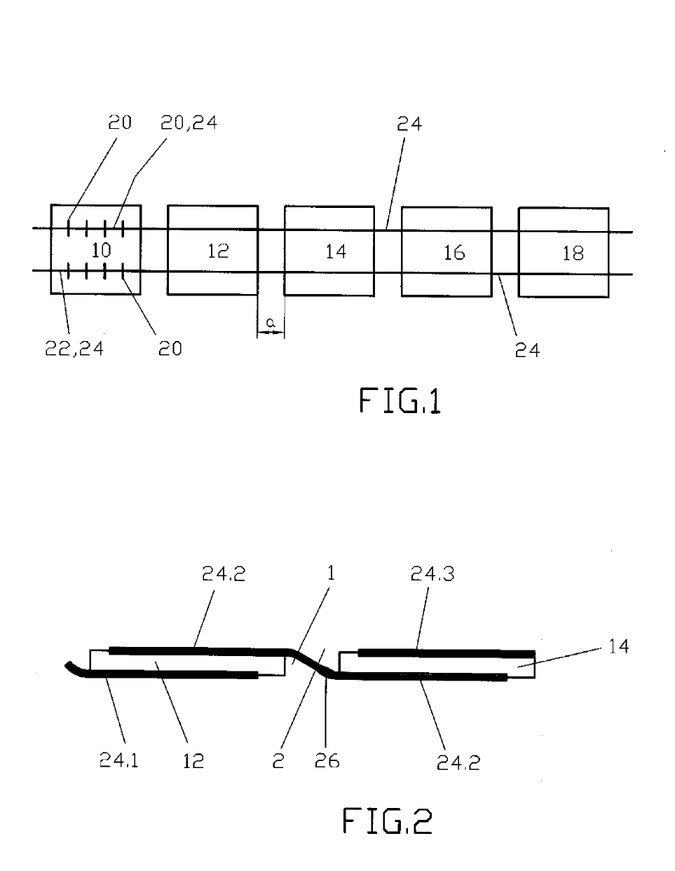

The photovoltaic module according to FIG. 1 comprises five solar cells 10, 12, 14, 16, 18. The view shows the n-doped main surfaces of the cells 10, 12, 14, 16, 18, which are arranged at a distance—a—from each other and in each case have a conductor track structure on their upper side, which comprises a multiplicity of contacts 20 which are arranged at a distance from each other and alternately connected with two so-called busbars 22 (only shown for cell 10). The busbars 22 are lying beneath the flat bands 24 described below.

On the upper side of the cell 10 shown, two flat bands 24 are soldered onto the two busbars 22, with the flat bands 24 extending beyond the cell 10 on the right and running under the adjacent cell 12, where they are soldered to the electrode which is arranged on the underside of the cell 12. This applies analogously to the connection of in each case two adjacent cells, with the flat bands 24 projecting beyond the cell 18 shown on the right in FIG. 1 at the end and forming electrical connections. This applies analogously for the cell 10.

FIG. 2 shows in side view an enlarged diagram of the cells 12, 14, including the flat bands 24 arranged thereon.

A first flat band 24.1, which comes from the cell 10, is soldered onto the underside of the cell 12. A further flat band 24.2, which is soldered to a corresponding busbar, runs on the upper side of the cell 12. The flat band 24.2 extends in the direction of the adjacent cell 14 in an S-shaped course under the underside of the cell 14, where it is soldered analogously to the flat band 24.1. A flat band 24.3, which runs to the cell 16, can be seen on the upper side of the cell 14.

For illustrative purposes, the material thickness of a coating 26 on a base body of the flat band 24.2 in the transition region between the cells 12 and 14 is shown exaggeratedly. It can be seen that the coating 26 does not run in a uniform material thickness on the main surfaces of the base body, but has thicker and thinner sections. This is a result of the production of the string shown, which has been produced as a unit comprising five cells 10, 12, 14, 16, 18 in a common soldering process. The source of heat is arranged above and/or below the entire string and acts on the string over its entire area. The effect of heat in the transition region between adjacent cells (in this case: 12, 14) has caused the coating material to deform and assume the geometry shown. At the symbolically shown section 1, the thickness of the coating 26 on the upper side of the base body is for example 8 μm and on the underside 15 μm, whereas the coating thickness at section 2 is 4 μm on the upper side and 30 μm on the underside.

It is of particular significance that no stepped changes in the coating thickness have formed in the transition region from the surface where the flat band 24.2 is placed on the cell 12 to the exposed region, but rather a soft, homogenous transition, which is essential for the fact that the flat band 24.2 is less susceptible to breakage than in the prior art.

Furthermore, the described production method has the advantage that a homogenous heat pattern over the entire string also produces an extreme reduction in breakage for the cells, and the soldering process is made considerably faster overall, as now all the cells are soldered at the same time.

Having described the invention, the following is claimed:

1. Photovoltaic module with the following features:
a plurality of plate-shaped cells (10, 12, 14, 16, 18) which are arranged at a distance from each other and flush with each other
each cell (10, 12, 14, 16, 18) has a conductor track structure (22, 24) which forms a first electrode on a first main surface, and a second main surface is configured in each case as a second electrode with opposed polarity,
all cells (10, 12, 14, 16, 18) are oriented identically with respect to their main surfaces,
adjacent cells (10,12; 12,14; 14,16; 16,18; 18,20) are electrically connected in each case by means of at least one flat band (24),
the flat band (24) has a solderable coating (26) on a base body,
the flat band (24) is soldered with a first section to the first electrode of one cell (10, 12, 14, 16, 18) and with a second section to the second electrode of an adjacent cell (12, 14, 16, 18), wherein
the coating (26) in the section between adjacent cells (10,12; 12,14; 14,16; 16,18; 18,20) at at least two points (1, 2) has material thicknesses which deviate from each other by at least 30%, relative to the base body of the flat band (24).

2. Photovoltaic module according to claim 1, in which the coating (26) in the section between adjacent cells (10,12; 12,14; 14,16; 16,18; 18,20) at at least two points (1, 2) has material thicknesses which deviate from each other by at least 40%.

3. Photovoltaic module according to claim 1, in which the coating (26) in the section between adjacent cells (10,12; 12,14; 14,16; 16,18; 18,20) at at least two points (1, 2) has material thicknesses which deviate from each other by at least 60%.

4. Photovoltaic module according to claim 1, in which the coating (26) in the section between adjacent cells (10,12; 12,14; 14,16; 16,18; 18,20) at at least two points (1, 2) has material thicknesses which deviate from each other by at least 80%.

5. Method for producing a photovoltaic module according to claim 1, with the following features:
a first cell is placed on a support,
at least one flat band is placed with one section on the exposed first electrode of the first cell,
a second cell is placed on the second section of the flat band in such a manner that it lies at a distance from the first cell and the second electrode of the second cell contacts the second section of the flat band,
the steps 5.2 and 5.3 are then repeated until the module comprises n cells,
the module with n cells is thermally loaded from at least one side in a subsequent method step in such a manner that a soldered connection is produced between the flat bands and corresponding electrodes of the cells,
the support with the module lying on it is then fed to further process steps.

6. Method according to claim 5, in which the cells are placed into corresponding depressions in the support.

7. Method according to claim 5, in which the cells are thermally treated using halogen light.

8. Method according to claim 5, having a plurality of heat sources, which are arranged in front of the cells at a distance from both main surfaces of the cells.
